(19) United States
(12) Patent Application Publication
(10) Pub. No.: US 2018/0313399 A1
(43) Pub. Date: Nov. 1, 2018

(54) HINGE AND ELECTRONIC APPARATUS

(71) Applicant: FUJITSU LIMITED, Kawasaki-shi (JP)

(72) Inventor: Yutaka Nakamura, Atsugi (JP)

(73) Assignee: FUJITSU LIMITED, Kawasaki-shi (JP)

(21) Appl. No.: 16/026,303

(22) Filed: Jul. 3, 2018

Related U.S. Application Data
(63) Continuation of application No. PCT/JP2016/052047, filed on Jan. 25, 2016.

(51) Int. Cl. F16C 11/04; H05K 5/02; H04M 1/02; G06F 1/16

(52) U.S. Cl. CPC F16C 11/045; H05K 5/0226; G06F 1/1641; G06F 1/1681; G06F 1/1618; H04M 1/0212

(57) ABSTRACT

A hinge includes a first member and a second member which are coupled to each other in an openable/closable manner. The first member includes a first protrusion protruding in a first direction and a first groove in an arc shape. The second member faces the first member in the first direction and includes a second protrusion which is fitted into the first groove and a second groove in an arc shape into which the first protrusion is fitted.

### CROSS-REFERENCE TO RELATED APPLICATION

This application is a continuation application of International Application PCT/JP2016/052047 filed on Jan. 25, 2016 and designated the U.S., the entire contents of which are incorporated herein by reference.

### FIELD

The present disclosure relates to a hinge and an electronic apparatus.

### BACKGROUND

A hinge is known in which a rotating shaft changes from a first rotating shaft to a second rotating shaft in the middle of an opening operation of a lid.

Related art is disclosed in Japanese Laid-open Patent Publication No. 6-53671.

### SUMMARY

According to one aspect of the embodiments, a hinge includes: a first member; and a second member coupled to the first member in such a manner that the first member and the second member couples to each other in an openable/closable manner, wherein the first member includes a first protrusion which protrudes in a first direction and a first groove in an arc shape, and the second member faces the first member in the first direction and includes a second protrusion which is fitted into the first groove and a second groove in an arc shape into which the first protrusion is fitted.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is an exploded view schematically illustrating a hinge according to Embodiment 1.

FIG. 2 is a view schematically illustrating an opening/closing operation of the hinge.

FIG. 3 is a view schematically illustrating the opening/closing operation of the hinge.

FIG. 4 is a view schematically illustrating the opening/closing operation of the hinge.

FIG. 5 is an enlarged view illustrating a relationship between an imaginary circle and a scale according to Embodiment 1.

FIG. 6 is an explanatory view of an electronic apparatus using a hinge according to a comparative example.

FIG. 7 is an explanatory view of the electronic apparatus using a hinge according to a comparative example.

FIG. 8 is a side view schematically illustrating an electronic apparatus using the hinge according to Embodiment 1.

FIG. 9 is a perspective view illustrating a hinge (closed state) according to Embodiment 2.

FIG. 10 is a perspective view illustrating the hinge (open state).

FIG. 11 is an exploded view illustrating the hinge.

FIG. 12 is a perspective view illustrating a state of an electronic apparatus when the hinge is in the closed state.

FIG. 13 is a side view illustrating a state of the electronic apparatus when the hinge is in the closed state.

FIG. 14 is an enlarged view of an X1 portion of FIG. 13.

FIG. 15 is a perspective view illustrating a state of the electronic apparatus when the hinge is in the open state.

FIG. 16 is a side view illustrating a state of the electronic apparatus when the hinge is in the open state.

FIG. 17 is an enlarged view of an X2 portion of FIG. 16.

FIG. 18 is an exploded view schematically illustrating a hinge according to Embodiment 3.

FIG. 19 is a view schematically illustrating an opening/closing operation of the hinge.

FIG. 20 is a view schematically illustrating the opening/closing operation of the hinge.

FIG. 21 is a view schematically illustrating the opening/closing operation of the hinge.

FIG. 22 is an enlarged view illustrating a relationship between an imaginary circle and a scale according to Embodiment 3.

### DESCRIPTION OF EMBODIMENTS

With the hinge of the related art, it is difficult to support a flexible sheet-like member (hereinafter, also referred to as a “flexible member”) such as an organic ElectroLuminescence (EL) display by the hinge in an openable/closable manner. When an opening degree of the hinge is changed, slackness or tension is generated in the flexible member and a force due to slackness or tension is applied to the flexible member.

For example, a hinge or the like which can support a flexible member in an openable/closable manner may be provided.

Hereinafter, respective embodiments will be described in detail with reference to the drawings.

### Embodiment 1

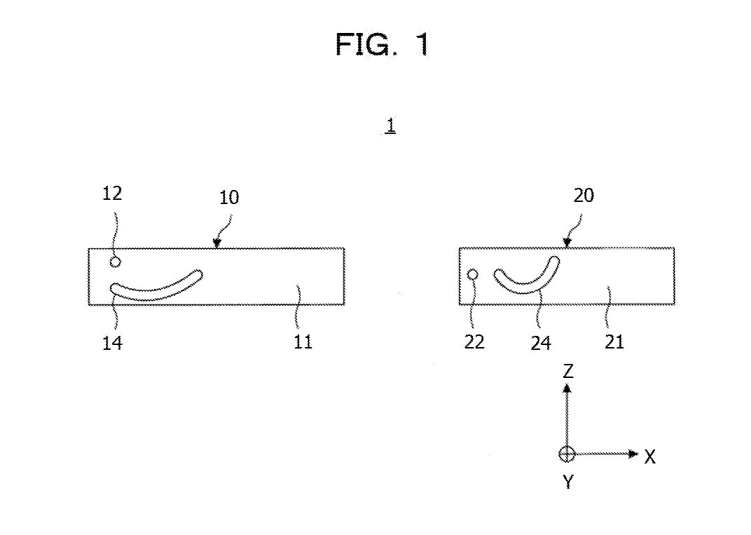

FIG. 1 is an exploded view schematically illustrating a hinge 1 according to Embodiment 1. In FIG. 1, X-, Y-, and Z-axes which are three axes orthogonal to each other are defined. Hereinafter, in a state illustrated in FIG. 1, a positive side in a Z-axis direction is defined as an “upper side” of a first member 10 and a second member 20.

The hinge 1 includes the first member 10 and the second member 20 which are coupled to each other in an openable/closable manner.

The first member 10 is a plate-like member and is made of, for example, resin. The first member 10 includes a flat surface portion 11 having a normal in a Y-axis direction. In addition, the first member 10 may include a curved surface portion in addition to the flat surface portion 11. In addition, in the example illustrated in FIG. 1, a shape of the first member 10 when viewed in the Y-axis direction is rectangular, but as long as it is a shape in which a first protrusion 12 and a first groove 14, which are described later, can be formed, any shape may be provided.

The first member 10 includes the first protrusion 12 protruding in the Y-axis direction and the first groove 14 having an arc shape. In addition, the arc shape is a concept including not only a shape corresponding to an arc of a single curvature radius but also a shape corresponding to an arc formed of a combination of two or more curvature radii.

The first protrusion 12 may be formed integrally with the first member 10 or may be attached to the first member 10. For example, the first protrusion 12 may be formed by a pin penetrating the first member 10.

The first groove 14 may be a groove recessed in the Y-axis direction. The first groove 14 may have a shape which has a bottom or may have a shape which does not have a bottom (that is, a hole shape). In Embodiment 1, as an example, it is supposed that the first groove 14 has the shape having a bottom.

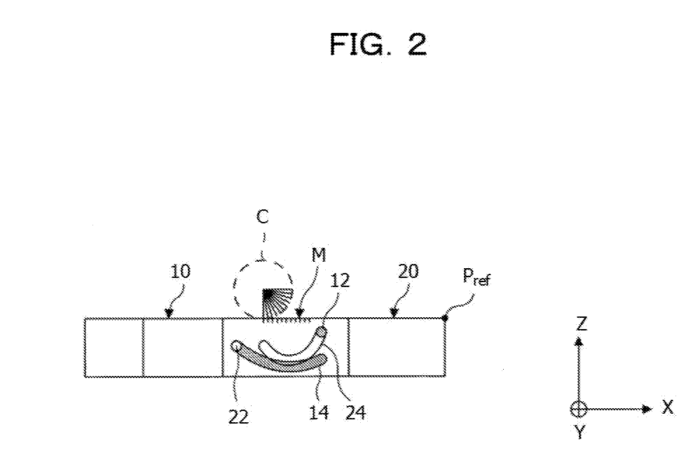

The second member 20 is a plate-like member and is made of, for example, resin. The second member 20 includes a flat surface portion 21 having a normal in the Y-axis direction. The second member 20 faces the first member 10 in an assembled state (see FIG. 2 described later). Specifically, the flat surface portion 11 of the first member 10 faces the flat surface portion 21 of the second member 20 in the Y-axis direction. In Embodiment 1, as an example, the flat surface portion 11 and the flat surface portion 21 are in surface contact with each other and have a sliding relationship. In addition, the second member 20 may include a curved surface portion in addition to the flat surface portion 21. In addition, in the example illustrated in FIG. 1, a shape of the second member 20 when viewed in the Y-axis direction is rectangular, but as long as it is a shape in which a second protrusion 22 and a second groove 24, which are described later, can be formed, any shape may be provided.

The second member 20 includes the second protrusion 22 protruding in the Y-axis direction and the second groove 24 having an arc shape.

The second protrusion 22 may be formed integrally with the second member 20 or may be attached to the second member 20. For example, the second protrusion 22 may be formed by a pin penetrating the second member 20.

The second groove 24 may be a groove recessed in the Y-axis direction. The second groove 24 may have a shape which has a bottom or may have a shape which does not have a bottom (that is, a hole shape). In Embodiment 1, as an example, it is supposed that the second groove 24 has the shape which does not have a bottom. As illustrated in FIG. 1, the second groove 24 has an arc shape different from the arc shape of the first groove 14. In an example illustrated in FIG. 1, the second groove 24 projects on the same side as the first groove 14 (in Embodiment 1, projecting downward). In addition, details of the arc shape of the second groove 24 (and the first groove 14) will be described later.

The first member 10 and the second member 20 are assembled to each other in such a manner that the first protrusion 12 of the first member 10 is fitted into the second groove 24 of the second member 20 and the second protrusion 22 of the second member 20 is fitted into the first groove 14 of the first member 10 (FIGS. 2 to 4).

Here, functions of the first protrusion 12, the first groove 14, the second protrusion 22, and the second groove 24 will be described together with an opening/closing operation of the hinge 1 with reference to FIGS. 2 to 4.

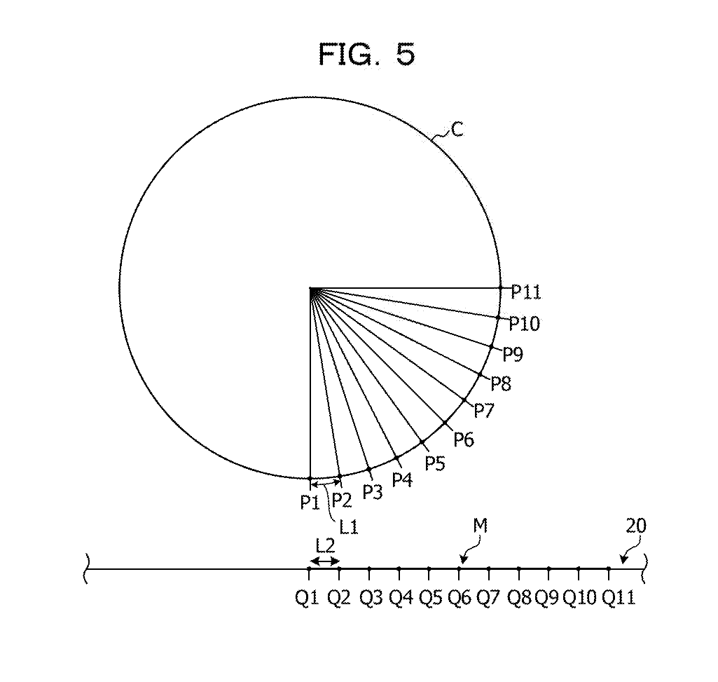

FIGS. 2 to 4 are views schematically illustrating the opening/closing operation of the hinge 1. FIG. 5 is an enlarged view illustrating a relationship between an imaginary circle and a scale. In addition, since the assembled state is illustrated in FIGS. 2 to 4, unlike FIG. 1, the flat surface portion 11 of the first member 10 faces the positive side in the Y-axis direction.

In FIGS. 2 to 4, for the purpose of explanation, an imaginary circle C is illustrated and line segments obtained by equally dividing 90 degrees into 10 are illustrated in the imaginary circle C. Intersection points of the respective line segments with the imaginary circle are illustrated by P1 to P11 in FIG. 5. In addition, for the purpose of explanation, a scale M is illustrated on an upper side of the second member 20. The scale M is illustrated with respective points Q1 to Q11 (see FIG. 5) obtained by being equally divided into ten. In FIGS. 2 to 4, for the purpose of explanation, the first protrusion 12 and the first groove 14 are hatched with “mat finish” and the first groove 14 and a part (second protrusion 22 or the like) of the second member 20 are illustrated in perspective. In addition, in FIG. 5, for the purpose of explanation, the imaginary circle C and the scale M are illustrated separately in the Z-axis direction, but actually, as illustrated in FIGS. 2 to 4, the imaginary circle C and the scale M are in a relationship to be in contact with each other. In addition, a distance L1 between the respective adjacent points P1 to P11 is equal to a distance L2 between respective adjacent points Q1 to Q11.

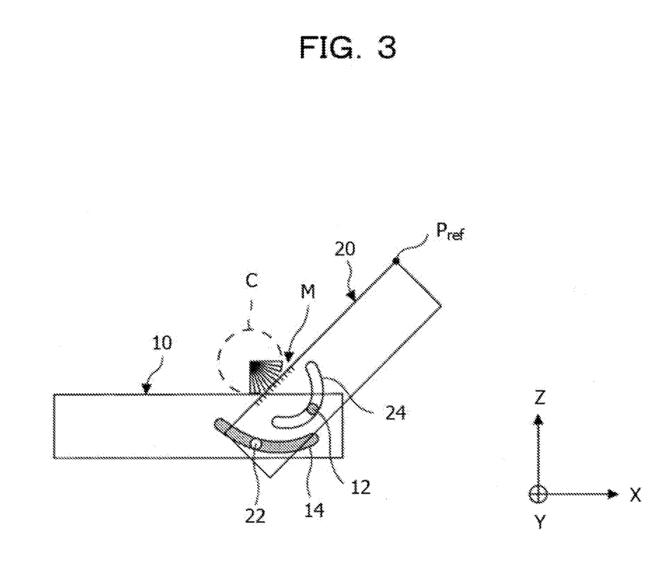

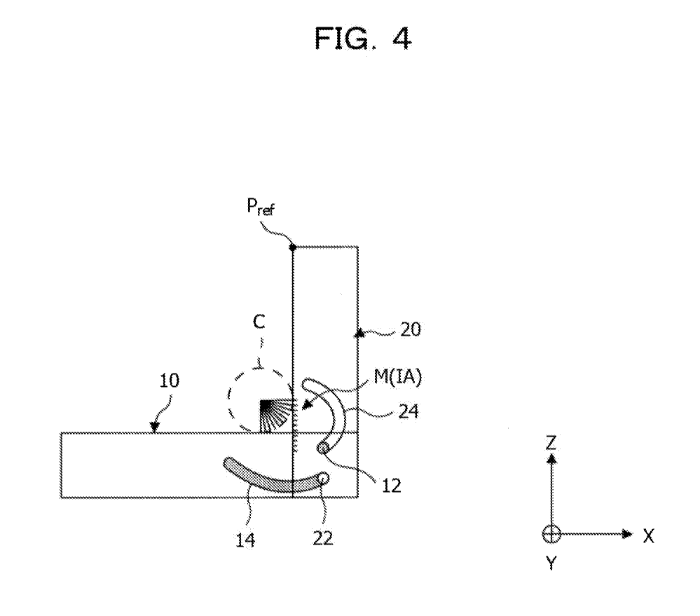

FIG. 2 illustrates a state where an opening degree of the hinge 1 is 0 degrees, FIG. 3 illustrates a state where the opening degree of the hinge 1 is 45 degrees, and FIG. 4 illustrates a state where the opening degree of the hinge 1 is 90 degrees. In addition, in Embodiment 1, as an example, the opening degree of the hinge 1 equal to the opening degree of the second member 20 with respect to the first member 10, and a variable range of the opening degree of the hinge 1 is 90 degrees. The opening degree of the second member 20 with respect to the first member 10 is defined as 0 degrees when a longitudinal direction of the second member 20 coincides with the X-axis direction in a state where a longitudinal direction of the first member 10 is fixed parallel to the X-axis, and indicates an angle of change from 0 degrees between the longitudinal direction of the second member 20 and the X-axis direction. Hereinafter, the opening direction indicates a direction in which the opening degree increases and the closing direction indicates a direction in which the opening degree decreases.

As illustrated in FIGS. 2 to 4, the imaginary circle C is in contact with the upper side of the second member 20 from above and a contact point when the opening degree is 0 degrees is P1 (see FIG. 5). In addition, a contact point on the second member 20 side when the opening degree is 0 degrees is Q1 (see FIG. 5). In the example illustrated in FIGS. 2 to 5, a radius of the imaginary circle C is not changed and a center of the imaginary circle C is a fixed point (that is, a point that does not move during the opening/closing operation of the hinge 1).

As illustrated in FIGS. 2 to 4, the second member 20 is displaced relative to the first member 10 in such a manner that the second protrusion 22 fitted into the first groove 14 moves along the first groove 14 and the first protrusion 12 fitted into the second groove 24 moves along the second groove 24. At this time, as illustrated in FIGS. 2 to 4, a relative displacement between the first member 10 and the second member 20 is defined by combining a movement of the second protrusion 22 fitted into the first groove 14 and a movement of the first protrusion 12 fitted into the second groove 24. That is, the relative displacement between the first member 10 and the second member 20 is not defined only by a relationship between the first groove 14 and the second protrusion 22, or only by a relationship between the second groove 24 and the first protrusion 12. The first member 10 and the second member 20 are regulated by both the relationship between the first groove 14 and the second protrusion 22 and the relationship between the second groove 24 and the first protrusion 12 so that the relative displacement with respect to each other does not vary.

The second member 20 is displaced relative to the first member 10 preferably in such a manner that a certain fixed point (for example, an end point P_{ref} on the upper side) traces an involute curve when viewed in the Y-axis direction. In other words, the position of the first protrusion 12, the arc shape of the first groove 14, the position of the second protrusion 22, and the arc shape of the second groove 24 are designed so that a certain fixed point traces an involute curve when viewed in the Y-axis direction when the second member 20 is displaced relative to the first member 10. Specifically, as illustrated in FIGS. 2 to 4, the second member 20 is displaced relative to the first member 10 in such a manner that the respective points Q1 to Q11 on the upper side are in contact with respective points P1 to P11 on a circumference of the imaginary circle C. For example, when the opening degree is 9 degrees, the point Q2 on the upper side of the second member 20 is in contact with the point P2 on the circumference of the imaginary circle C. Similarly, for example, when the opening degree is 45 degrees, the point Q6 on the upper side of the second member 20 is in contact with the point P6 on the circumference of the imaginary circle C (see FIG. 3). Similarly, for example, when the opening degree is 90 degrees, the point Q11 on the upper side of the second member 20 is in contact with the point P11 on the circumference of the imaginary circle C (see FIG. 4).

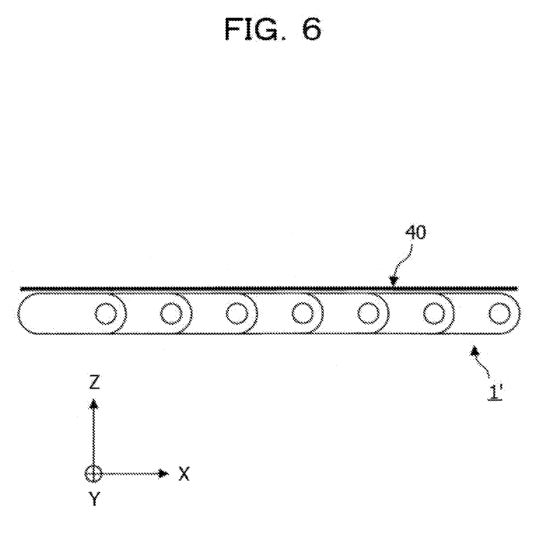

Next, an electronic apparatus using the hinge 1 according to Embodiment 1 will be described with reference to FIGS. 6 to 8.

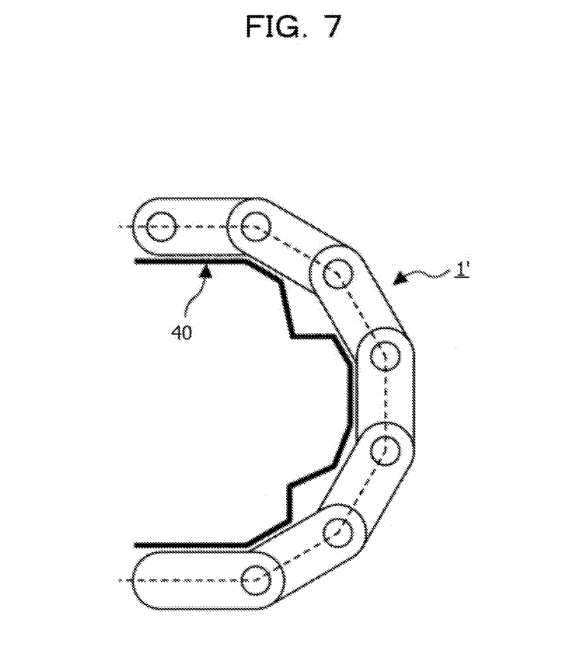

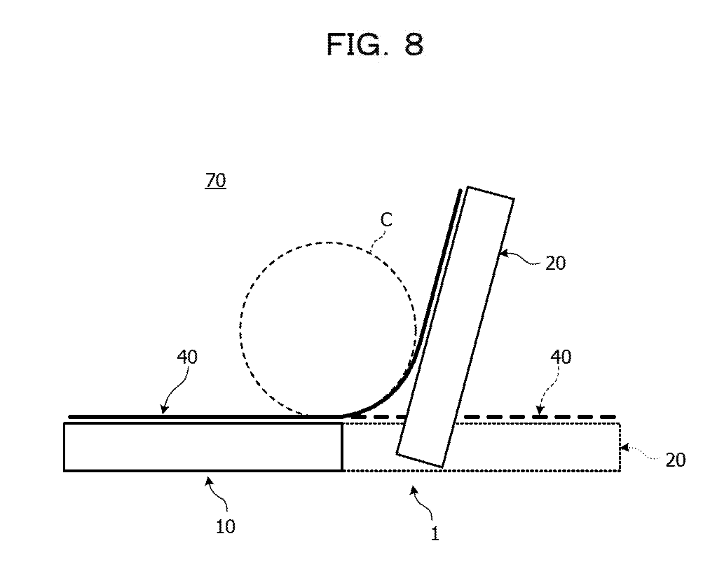

FIGS. 6 and 7 are explanatory views of the electronic apparatus using a hinge 1′ according to a comparative example. FIG. 8 is a side view schematically illustrating an electronic apparatus 70 using the hinge 1 according to Embodiment 1. Since FIG. 6 is a view for describing a principle, a detailed structure is not illustrated and only an organic EL display 40 is illustrated. In the comparative example, the organic EL display 40 is regulated by both end portions (both end portions in the X axis direction) of the hinge 1′.

The electronic apparatus 70 may be a portable information terminal such as a tablet, a mobile phone, a personal digital assistant (PDA), or a smartphone, a portable game machine, a portable music player, or the like. The electronic apparatus 70 includes the hinge 1 and the organic EL display 40. The organic EL display 40 is an example of a display device having flexibility. The organic EL display 40 is supported by the hinge 1 in such a manner that a display surface side thereof is recessed in the open state of the hinge 1. A part of the organic EL display 40 is regulated by the first member 10 of the hinge 1 and another part of the organic EL display 40 is regulated by the second member 20 of the hinge 1. In the example illustrated in FIG. 8, both sides of the organic EL display 40 in the X-axis direction (both sides excluding a center portion) are regulated by the first member 10 and the second member 20. In addition, in the example illustrated in FIG. 8, the first member 10 and the second member 20 directly support the organic EL display 40 in an openable/closable manner, but the first member 10 and the second member 20 may support the organic EL display 40 via another member in an openable/closable manner. That is, in the example illustrated in FIG. 8, the first member 10 and the second member 20 are respectively formed as part of two separated housing portions (an example of a supported member) of the electronic apparatus 70, but may be respectively attached to the two separated housing portions of the electronic apparatus 70.

The hinge 1′ according to the comparative example is an articulated hinge. In this case, as schematically illustrated in FIG. 7, if the opening degree of the hinge 1′ increases, a surface shape of the organic EL display 40 may not follow a surface formed by the hinge 1′. That is, the organic EL display 40 may not follow the surface shape of the hinge 1′ by simple bending, and as schematically illustrated in FIG. 7, slackness is generated in the organic EL display 40. As a result, a force due to slackness is applied to the organic EL display 40. In addition, since the organic EL display 40 does not bend if the curvature radius is 0 (zero), elongation or contraction is generated in the organic EL display 40. In addition, on the contrary, if the organic EL display 40 is regulated so as to follow the surface shape of the hinge 1′ in a state where the opening degree increases, tension is generated in the organic EL display 40 when the opening degree is small. As a result, similarly, a force due to tension is applied to the organic EL display 40. Therefore, in the hinge 1′ according to the comparative example, it is substantially difficult to support the organic EL display 40 in an openable/closable manner.

On the other hand, according to Embodiment 1, it is possible to suppress an undesirable force being applied to the organic EL display 40 along with the hinge 1 being opened/closed. Therefore, it is possible to support the organic EL display 40 in an openable/closable manner. Specifically, as schematically illustrated in FIG. 8, when the second member 20 is displaced relative to the first member 10, the organic EL display 40 on the second member 20 is separated from the second member 20, bent, and deformed, in such a manner of being wound around the imaginary circle C. Here, as described above, in a state where the opening degree is larger than 0, a length of the circumference of a range, in which the organic EL display 40 is wound around the imaginary circle C, is equal to a length of a straight line (see the scale M) in a range in which the organic EL display 40 is separated from the upper side of the second member 20. Therefore, according to Embodiment 1, in the organic EL display 40, slackness or tension are substantially not generated regardless of the opening degree of the hinge 1. In this manner, according to Embodiment 1, it is possible to reduce the force due to slackness or tension generated by the organic EL display 40 with opening/closing of the hinge 1. Further, as a result, according to Embodiment 1, it is possible to support the organic EL display 40 by using the hinge 1 in an openable/closable manner.

In addition, in Embodiment 1, as a preferable example, the second member 20 is displaced relative to the first member 10 in such a manner that a certain fixed point traces an involute curve when viewed in the Y-axis direction, but the example is not limited thereto. Specifically, the second member 20 may be displaced relative to the first member 10 in such a manner that a certain fixed point traces a curve close to the involute curve when viewed in the Y-axis direction. For example, in Embodiment 1, the radius of the imaginary circle C is not changed, but the position of the first protrusion 12, the arc shape of the first groove 14, the position of the second protrusion 22, and the arc shape of the second groove 24 may be designed by using an imaginary circle in which a radius decreases as the opening degree increases.

### Embodiment 2

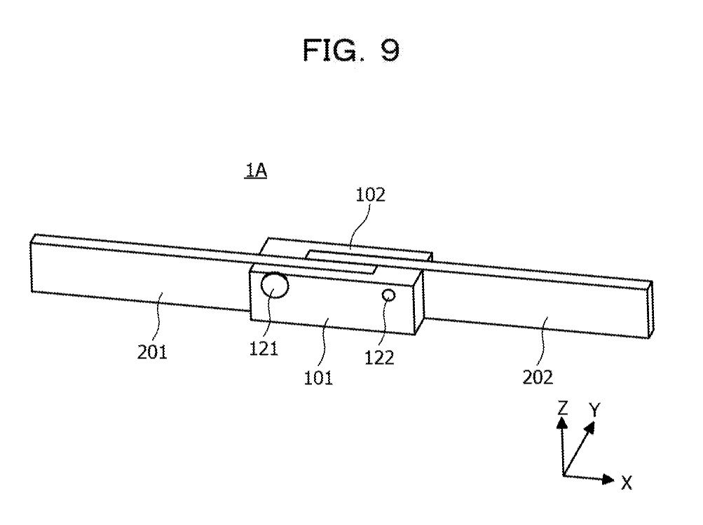

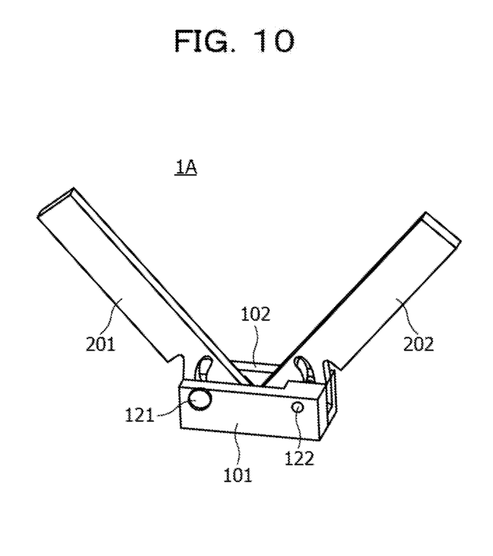

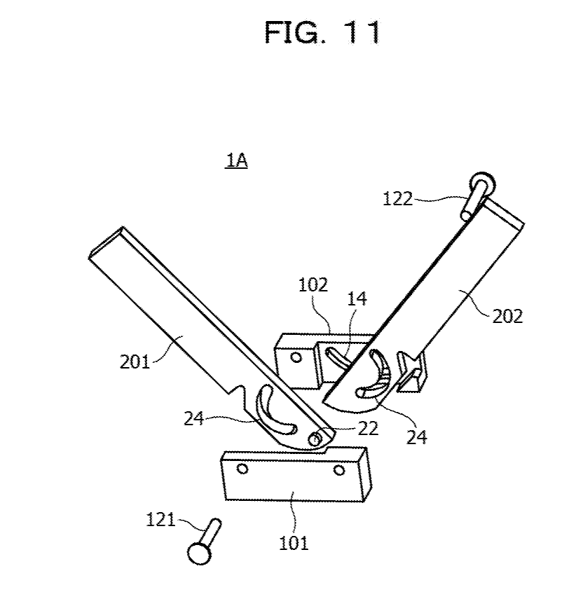

FIGS. 9 and 10 are perspective views illustrating a hinge 1A according to Embodiment 2. FIG. 9 illustrates the hinge 1A of a closed state (opening degree is 0) and FIG. 10 illustrates the hinge 1A of an open state. FIG. 11 is an exploded view illustrating the hinge 1A.

The hinge 1A according to Embodiment 2 is different from the hinge 1 according to Embodiment 1 described above in that the combination of the first member 10 and the second member 20 is replaced by a combination of two sets of first members 101 and 102 and second members 201 and 202. That is, Embodiment 2 substantially corresponds to a configuration including two sets of the combination of the first member 10 and the second member 20 according to Embodiment 1 described above. Two or more sets of the combination of the first member 10 and the second member 20 according to Embodiment 1 described above are provided, so that it is possible to increase a relative displacement amount of the hinge 1A. Hereinafter, the same reference numerals are given to the substantially same configurations as those of Embodiment 1 described above and the description thereof will be omitted.

The hinge 1A includes the first members 101 and 102, and the second members 201 and 202. The first member 101 and the second member 201 form a set, and the first member 102 and the second member 202 form another set.

The first members 101 and 102 respectively include first protrusions 121 and 122 protruding in the Y-axis direction, and first grooves 14 in an arc shape. In addition, since the first groove 14 of the first member 101 is formed on a side facing the second member 202, the first groove 14 is not visible in FIGS. 9 to 11. The first members 101 and 102 are fixed to each other.

The second members 201 and 202 respectively include second protrusions 22 protruding in the Y-axis direction and second grooves 24 in an arc shape. In addition, since the second protrusion 22 of the second member 202 is formed on a side facing the first member 102, the second protrusion 22 is not visible in FIGS. 9 to 11. The second members 201 and 202 are displaced independently of each other. In the example illustrated in FIGS. 9 to 11, the second members 201 and 202 abut against each other in the Y-axis direction, but the second members 201 and 202 do not regulate a degree of freedom of a movement in an XZ plane (that is, the second members 201 and 202 are in a relationship of being capable of sliding with respect to each other in the XZ plane).

The first protrusion 121 of the first member 101 is fitted into the second groove 24 of the second member 201 and the second protrusion 22 of the second member 201 is fitted into the first groove 14 of the first member 101. The first protrusion 122 of the first member 102 is fitted into the second groove 24 of the second member 202 and the second protrusion 22 of the second member 202 is fitted into the first groove 14 of the first member 102.

The second member 201 is displaced relative to the first member 101. The second member 201 is displaced relative to the first member 101 in such a manner that the second protrusion 22 fitted into the first groove 14 of the first member 101 moves along the first groove 14, and the first protrusion 121 of the first member 101 fitted into the second groove 24 moves along the second groove 24. In this case, similar to Embodiment 1 described above, the second member 201 is displaced relative to the first member 101 in such a manner of preferably tracing an involute curve. As illustrated in FIG. 10, the opening direction of the second member 201 with respect to the first member 101 corresponds to a clockwise direction when viewed in a positive direction of the Y-axis.

The second member 202 is displaced relative to the first member 102. The second member 202 is displaced relative to the first member 102 in such a manner that the second protrusion 22 fitted into the first groove 14 of the first member 102 moves along the first groove 14, and the first protrusion 122 of the first member 102 fitted into the second groove 24 moves along the second groove 24. In this case, similar to Embodiment 1 described above, the second member 202 is displaced relative to the first member 102 in such a manner of preferably tracing an involute curve. The opening direction of the second member 202 with respect to the first member 102 is opposite to the opening direction of the second member 201 with respect to the first member 101 and as illustrated in FIG. 10, corresponds to a counterclockwise direction when viewed in the positive direction of the Y-axis. Therefore, it is possible to increase a range in which an angle (see an angle α described later) is formed between the second member 201 and the second member 202.

According to Embodiment 2, the same effects as those of Embodiment 1 described above can be obtained. In addition, in Embodiment 2, two sets including the set of the first member 101 and the second member 201, and the set of the first member 102 and the second member 202 are used, so that it is possible to increase the relative displacement amount of the hinge 1A compared to the relative displacement amount of the case of one set.

In addition, in Embodiment, the set of the first member 101 and the second member 201, and the set of the first member 102 and the second member 202 are provided adjacent to each other in the Y-axis direction, but may be provided separated from each other in the Y-axis direction.

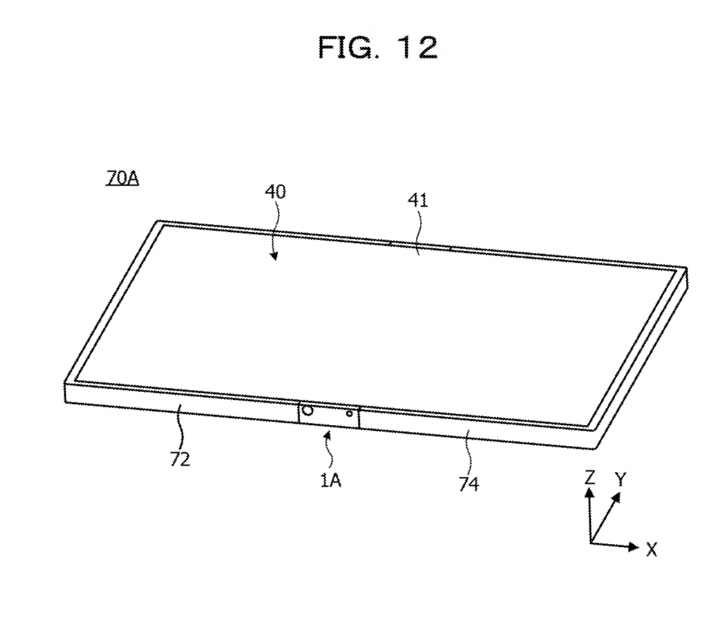

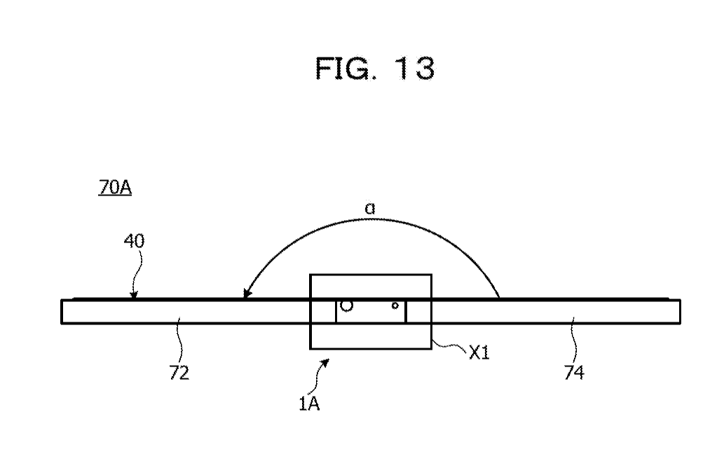

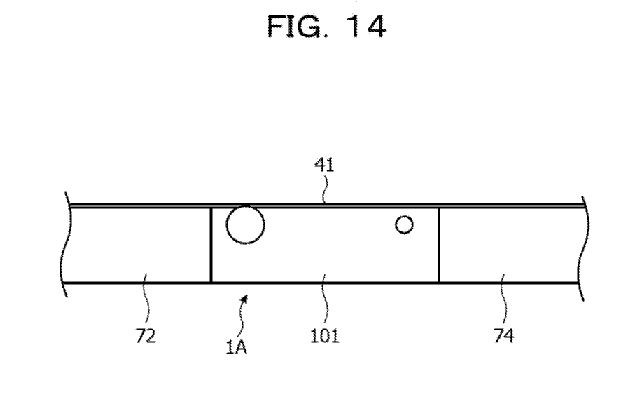

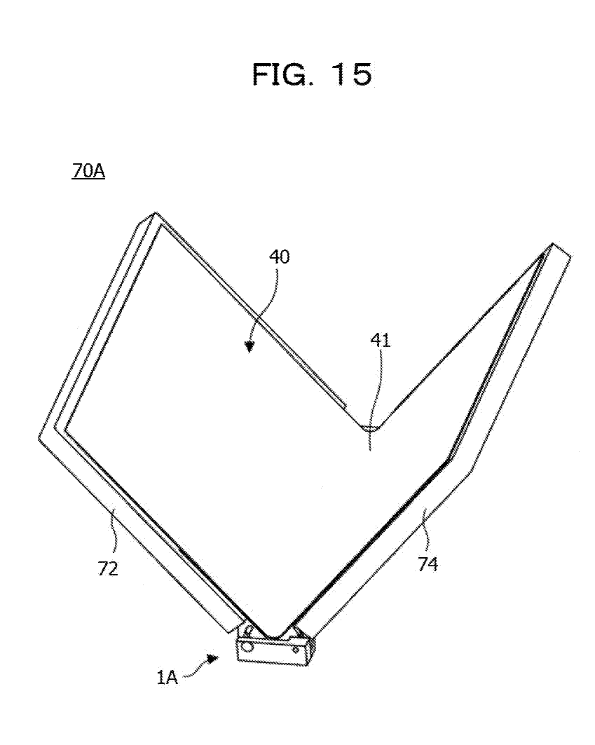

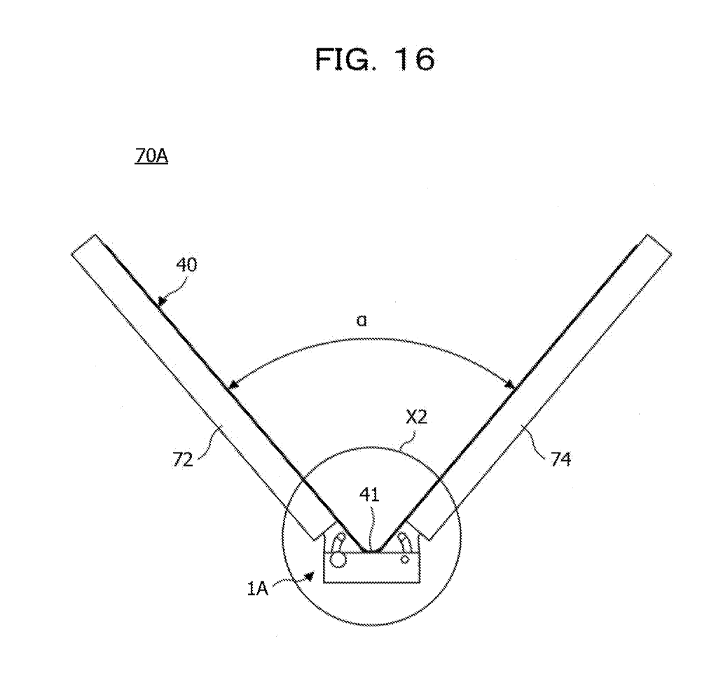

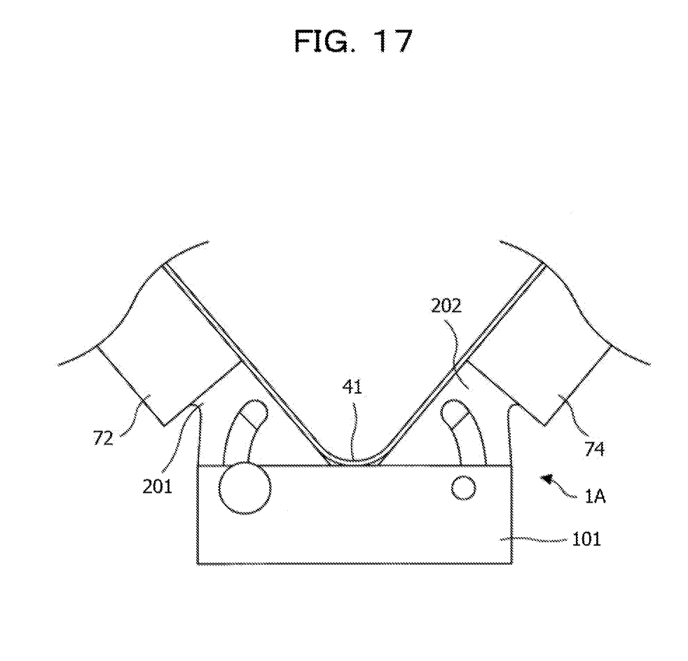

FIGS. 12 to 17 are views illustrating an example of an electronic apparatus 70A using the hinge 1A. FIGS. 12 and 13 are respectively a perspective view and a side view illustrating a state of the electronic apparatus 70A when the hinge 1A is in a closed state. FIG. 14 is an enlarged view of an X1 portion of FIG. 13. FIGS. 15 and 16 are respectively a perspective view and a side view illustrating a state of the electronic apparatus 70A when the hinge 1A is in the open state. FIG. 17 is an enlarged view of an X2 portion of FIG. 16.

The electronic apparatus 70A may be a portable information terminal such as a smartphone as described above.

The electronic apparatus 70A includes a hinge 1A, an organic EL display 40, a first housing portion 72 (example of a supported member or a first supported member), and a second housing portion 74 (example of a supported member or a second supported member).

The hinge 1A is provided between the first housing portion 72 and the second housing portion 74 in the X-axis direction. Two or more hinges 1A may be provided side by side in the Y-axis direction. For example, the hinges 1A may be respectively provided at both ends of the electronic apparatus 70A in the Y-axis direction. The hinge 1A supports the organic EL display 40 via the first housing portion 72 and the second housing portion 74 in an openable/closable manner.

The organic EL display 40 is provided over both the first housing portion 72 and the second housing portion 74. The first housing portion 72 regulates a part of the organic EL display 40 and the second housing portion 74 regulates another part of the organic EL display 40. In the example illustrated in FIGS. 12 to 17, the organic EL display 40 has a structure in which both sides of a center portion 41 in the X-axis direction except for the center portion 41 in the X-axis direction are respectively fixed to the first housing portion 72 and the second housing portion 74.

The first housing portion 72 and the second housing portion 74 are separate bodies and are coupled via the hinge 1A. That is, the first housing portion 72 is fixed to the second member 201 and the second housing portion 74 is fixed to the second member 202. The first housing portion 72 and the second housing portion 74 accommodate elements (for example, a control board, an antenna, and the like) inside the electronic apparatus 70A. In addition, a display on the organic EL display 40 is controlled by a processing device (not illustrated) on the control board inside the electronic apparatus 70A.

According to the example illustrated in FIGS. 12 to 17, since the organic EL display 40 is supported by the hinge 1A in an openable/closable manner, it is possible to reduce a force due to slackness or tension generated by the organic EL display 40 along with opening/closing of the hinge 1A. Specifically, as illustrated in FIG. 17, in the open state of the hinge 1A, the organic EL display 40 does not have slackness but only bends and deforms. In addition, as illustrated in FIG. 14, in the closed state of the hinge 1A, the organic EL display 40 is not subjected to tension.

In addition, according to the example illustrated in FIGS. 12 to 17, it is easy to secure a requisite variable range with respect to the angle α (see FIGS. 13 and 16) formed by a surface of the first housing portion 72 and a surface of the second housing portion 74. In the hinge 1A according to Embodiment 2, as an example, a range possible for an angle of the second member 201 with respect to the first member 101 is 90 degrees and a range possible for an angle of the second member 202 with respect to the first member 102 is 90 degrees. Therefore, the variable range of the opening degree of the hinge 1A is 180 degrees in total. In addition, the angle α formed by the surface of the first housing portion 72 and the surface of the second housing portion 74 is 180 degrees in the closed state of the hinge 1A as illustrated in FIG. 13 and is 0 degrees in a full open state (not illustrated) of the hinge 1A. Therefore, the variable range of the opening degree of the hinge 1A from the closed state is within a range (0 degrees a 180 degrees) in which a display surface side of the organic EL display 40 is recessed.

In addition, in the example illustrated in FIGS. 12 to 17, the second member 201 and the second member 202 are respectively attached to the first housing portion 72 and the second housing portion 74, but may be formed integrally with the first housing portion 72 and the second housing portion 74 respectively. For example, a part or whole of each of the second member 201 and the second member 202 may be formed integrally with each of the first housing portion 72 and the second housing portion 74.

### Embodiment 3

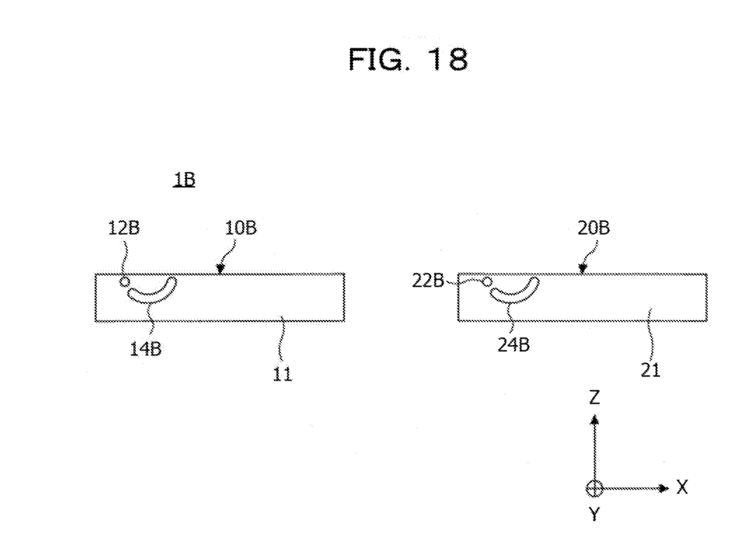

FIG. 18 is an exploded view schematically illustrating a hinge 1B according to Embodiment 3. Hereinafter, the same reference numerals are given to the substantially same configurations as those of Embodiment 1 described above and the description thereof will be omitted.

The hinge 1B includes a first member 10B and a second member 20B which are coupled to each other in an openable/closable manner.

The first member 10B is different from the first member 10 according to Embodiment 1 described above in that the first protrusion 12 and the first groove 14 are respectively replaced by a first protrusion 12B and a first groove 14B. A position and a shape of the first groove 14B are different from those of the first groove 14 according to Embodiment 1 described above. A positional relationship of the first protrusion 12B with the first groove 14B is different from the positional relationship of the first protrusion 12 according to Embodiment 1 described above.

The second member 20B is different from the second member 20 according to Embodiment 1 described above in that the second protrusion 22 and the second groove 24 are replaced by a second protrusion 22B and a second groove 24B. A position and a shape of the second groove 24B are different from those of the second groove 24 according to Embodiment 1 described above. A positional relationship of the second protrusion 22B with the second groove 24B is different from the positional relationship of the second protrusion 22 according to Embodiment 1 described above.

The first groove 14B of the first member 10B has the same arc shape as the arc shape of the second groove 24B of the second member 20B, and a positional relationship between the first protrusion 12B and the first groove 14B has the same positional relationship between the second protrusion 22B and the second groove 24B. Therefore, the first member 10B and the second member 20B have the same relationship regarding the protrusion and the groove. That is, the first member 10B and the second member 20B have the same configuration. However, the first member 10B and the second member 20B may be different from each other in other portions (for example, a shape of a notch that may be formed at an end portion) than the relationship regarding the protrusion and the groove.

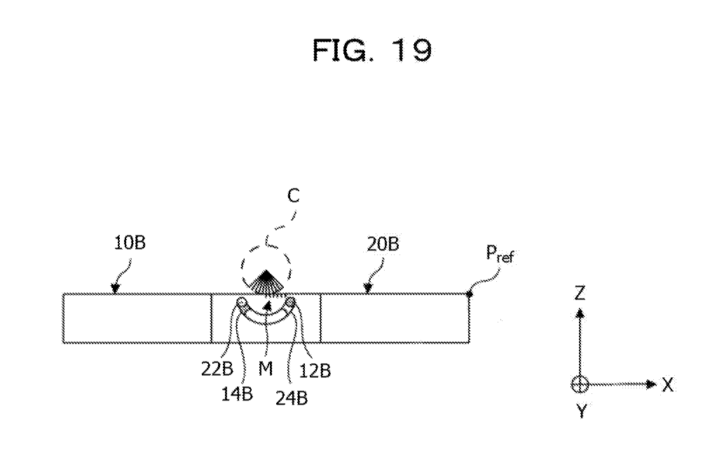

The first member 10B and the second member 20B are assembled to each other in such a manner that the first protrusion 12B of the first member 10B is fitted into the second groove 24B of the second member 20B and the second protrusion 22B of the second member 20B is fitted into the first groove 14B of the first member 10B (see FIGS. 19 to 21). In the assembled state, the first protrusion 12B and the first groove 14B of the first member 10B, and the second protrusion 22B and the second groove 24B of the second member 20B are symmetric with respect to the Z-axis when viewed in the Y-axis direction. The first member 10B and the second member 20B displace symmetrically relative to the Z-axis.

Here, functions of the first protrusion 12B, the first groove 14B, the second protrusion 22B, and the second groove 24B will be described together with an opening/closing operation of the hinge 1B with reference to FIGS. 19 to 21.

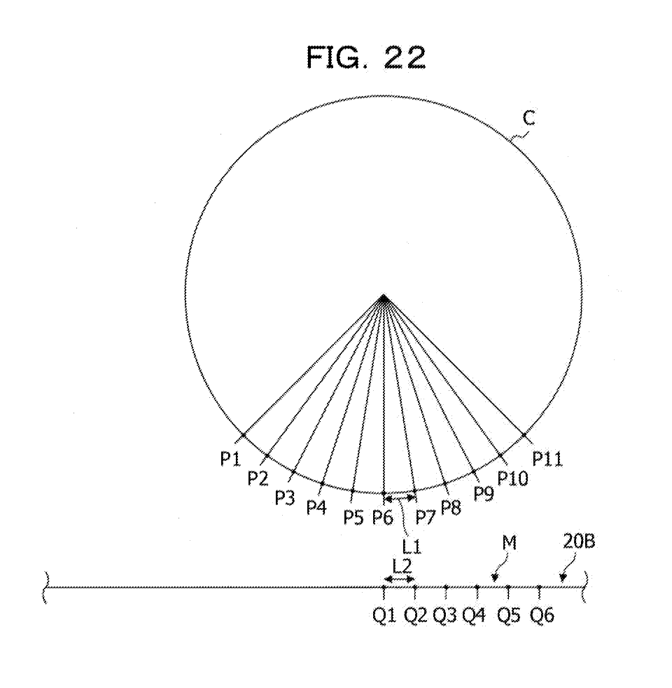

FIGS. 19 to 21 are views schematically illustrating the opening/closing operation of the hinge 1B. FIG. 22 is an enlarged view illustrating a relationship between an imaginary circle and a scale. The viewpoints of FIGS. 19 to 22 are the same as those of FIGS. 2 to 5 described above. For example, for the purpose of explanation, the same imaginary circle C as that described above is illustrated in FIGS. 19 to 21. In addition, for the purpose of explanation, the same scale M as that described above is illustrated on an upper side of the second member 20B in FIGS. 19 to 21. The scale M is indicated by respective points Q1 to Q6 (see FIG. 22) obtained by being equally divided into five.

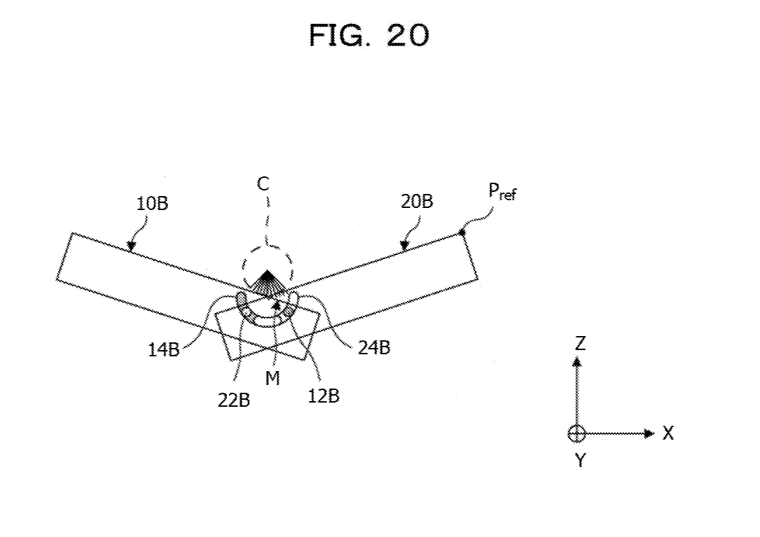

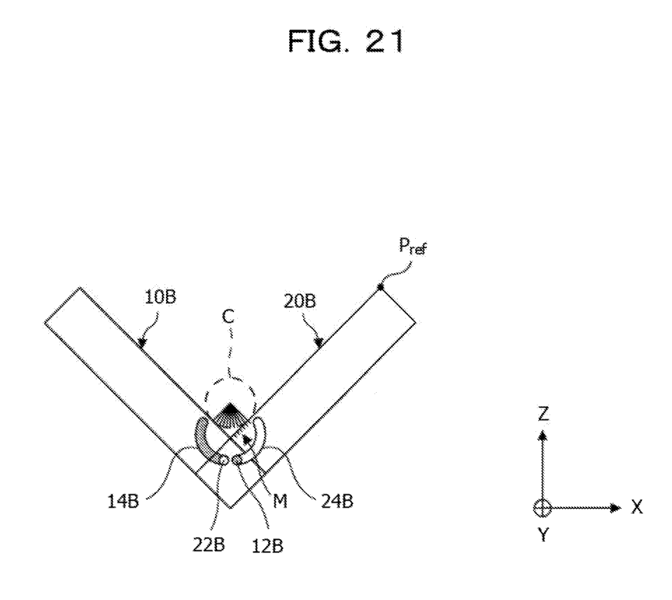

FIG. 19 illustrates a state where the opening degree of the hinge 1B is 0 degrees, FIG. 20 illustrates a state where the opening degree of the hinge 1B is 45 degrees, and FIG. 21 illustrates a state where the opening degree of the hinge 1B is 90 degrees. In addition, in Embodiment 3, as an example, the opening degree of the hinge 1B is equal to the opening degree of the second member 20B with respect to the first member 10B, and the variable range of the opening degree of the hinge 1B is 90 degrees.

As illustrated in FIGS. 19 to 21, the imaginary circle C is in contact with the upper side of the second member 20B from above and a contact point when the opening degree is 0 degrees is P6 (see FIG. 22). In addition, the contact point on a second member 20B side when the opening degree is 0 degrees is Q1 (see FIG. 22).

As illustrated in FIGS. 19 to 21, the second member 20B is displaced relative to the first member 10B in such a manner that the second protrusion 22B fitted into the first groove 14B moves along the first groove 14B and the first protrusion 12B fitted into the second groove 24B moves along the second groove 24B. In this case, as illustrated in FIGS. 19 to 21, the relative displacement between the first member 10B and the second member 20B is defined by a combination of the movement of the second protrusion 22B fitted into the first groove 14B and the movement of the first protrusion 12B fitted into the second groove 24B.

The second member 20B is displaced relative to the first member 10B in such a manner that a certain fixed point (for example, an end point P_{ref} on the upper side) preferably traces an involute curve when viewed in the Y-axis direction. Specifically, as illustrated in FIGS. 19 to 21, the second member 20B is displaced with respect to the first member 10B in such a manner that the respective points Q1 to Q6 on the upper side are in contact with respective points P6 to P11 on a circumference of the imaginary circle C. For example, when the opening degree is 18 degrees, the point Q3 on the upper side of the second member 20B is in contact with the point P8 on the circumference of the imaginary circle C (see FIG. 20). Similarly, for example, when the opening degree is 90 degrees, the point Q6 on the upper side of the second member 20B is in contact with the point P11 on the circumference of the imaginary circle C (see FIG. 21). In addition, the first member 10B has the same configuration as that of the second member 20B as described above.

According to Embodiment 3, the same effects as those of Embodiment 1 described above can be obtained. In addition, also in Embodiment 3, similar to Embodiment 2 described above, two or more sets of the first members 10B and the second members 20B can be provided. That is, in Embodiment 2 described above, the first members 101 and 102 may respectively have the same configuration as that of the second members 201 and 202.

Although each embodiment is described in detail, it is not limited to a specific embodiment and various modifications and changes are possible within the scope described in claims. In addition, it is also possible to combine all or two or more elements of the embodiments described above.

For example, in Embodiment 2 (also similar to Embodiments 1 and 3) described above, the organic EL display 40 projects downward (that is, the display surface side is recessed) in the open state of the hinge 1A, but the organic EL display 40 may project upward in the open state of the hinge 1. That is, the angle α formed by the surface of the first housing portion 72 and the surface of the second housing portion 74 may have a variable range included in a range of 180 degrees or more and 360 degrees or less. In this case, the second member 201 is preferably displaced relative to the first member 101 in such a manner of tracing an involute curve which projects downward. Similarly, the second member 202 is preferably displaced relative to the first member 102 in such a manner of tracing an involute curve which projects downward. In addition, in this case, the imaginary circle C illustrated in FIG. 19 or the like is disposed so as to be in contact with the upper side of the second member 20B from below.

In addition, in Embodiment 2 described above, the variable range of the angle α formed by the surface of the first housing portion 72 and the surface of the second housing portion 74 is the range of 0 degrees or more and 180 degrees or less, but other aspects may be provided. That is, the variable range of the angle α formed by the surface of the first housing portion 72 and the surface of the second housing portion 74 may be desirably set within the range of 0 degrees or more and 180 degrees or less.

In addition, in Embodiment 2 described above, the variable range of the angle α of the range of 0 degrees or more and 180 degrees or less is realized with two sets, but for example, the variable range of the angle α of the range of 0 degrees or more and 180 degrees or less may be realized with a larger number of sets such as four sets. For example, in a case of four sets, the variable range of the angle α per set may be 45 degrees.

In addition, in Example 1 (also similar to Embodiments 2 and 3) described above, the organic EL display 40 is illustrated as an example of the display device having flexibility, but for example, another thin display such as electronic paper may be used instead of the organic EL display 40.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A hinge comprising:
a first member; and
a second member coupled to the first member in such a manner that the first member and the second member couples to each other in an openable/closable manner, wherein
the first member includes a first protrusion which protrudes in a first direction and a first groove in an arc shape, and
the second member faces the first member in the first direction and includes a second protrusion which is fitted into the first groove and a second groove in an arc shape into which the first protrusion is fitted.

2. The hinge according to claim 1,
wherein a relative displacement between the first member and the second member is defined by a combination of a movement of the second protrusion which is fitted into the first groove and a movement of the first protrusion which is fitted into the second groove.

3. The hinge according to claim 1,
wherein the first member and the second member are displaced relative to each other in such a manner that at least one of the first member and the second member traces an involute curve when viewed in the first direction.

4. The hinge according to claim 1,
wherein entirety of each of the first groove and the second groove has an arc shape.

5. The hinge according to claim 1,
wherein the first groove and the second groove have different arc shapes from each other.

6. The hinge according to claim 1,
wherein the first groove and the second groove have an identical arc shape.

7. The hinge according to claim 1,
wherein two or more sets each including the first member and the second member are provided.

8. The hinge according to claim 7, wherein
the two or more first members are fixed to each other, and
the two or more second members are displaced independently of each other.

9. The hinge according to claim 7,
wherein at least two sets of the two or more sets each including the first member and the second member are provided such that opening directions of the second members with respect to the first members are opposite to each other.

10. The hinge according to claim 1, wherein
the hinge supports two supported members in an openable/closable manner, and
one of the two supported members regulates a part of a display device having flexibility and the other of the two supported members regulates another part of the display device.

11. The hinge according to claim 10,
wherein a variable range of an opening degree of the hinge from a closed state is within a range in which a display surface side of the display device is recessed.

12. The hinge according to claim 10, wherein
the first member is formed in or attached to one of the two supported members, and
the second member is formed in or attached to the other of the two supported members.

13. The hinge according to claim 7, wherein
the hinge supports two supported members in an openable/closable manner,
one of the two supported members regulates a part of a display device having flexibility and the other of the two supported members regulates another part of the display device,
one of the two or more second members is formed in or attached to one of the two supported members, and
another one of the two or more second members is formed in or attached to the other of the two supported members.

14. The hinge according to claim 1, wherein
the first member has a flat surface portion where the first protrusion and the first groove are formed, a normal to the flat surface portion extending in the first direction,
the second member has a flat surface portion where the second protrusion and the second groove are formed, a normal to the flat surface portion extending in the first direction, and
the flat surface portion of the first member and the flat surface portion of the second member face each other in the first direction.

15. The hinge according to claim 1, wherein
the first member and the second member are each displaced relative to each other in such a manner that the first member and the second member are in contact with an imaginary circle over an entire variable range of an opening degree of the hinge when viewed in the first direction, and
the imaginary circle has a constant radius and a constant center position over the entire variable range of the opening degree.

16. The hinge according to claim 1, wherein
a display device having flexibility is supported in an openable/closable manner, and
the first groove and the second groove have an arc shape in which a display surface side of the display device is recessed when viewed in the first direction.

17. The hinge according to claim 3, wherein
the hinge supports a display device having flexibility in an openable/closable manner, and
the involute curve projects on a display surface side of the display device.

18. An electronic apparatus comprising:
a display device having flexibility;
a first supported member that regulates a part of the display device;
a second supported member that supports another part of the display device; and
a hinge that supports the first supported member and the second supported member in an openable/closable manner, wherein
the hinge includes
a first member including a first protrusion which protrudes in a first direction and a first groove in an arc shape, and
a second member which faces the first member in the first direction and includes a second protrusion which is fitted into the first groove and a second groove in an arc shape into which the first protrusion is fitted.

19. The electronic apparatus according to claim 18,
wherein a relative displacement between the first member and the second member is defined by a combination of a movement of the second protrusion which is fitted into the first groove and a movement of the first protrusion which is fitted into the second groove.

20. The electronic apparatus according to claim 18,
wherein the first member and the second member are displaced relative to each other in such a manner that at least one of the first member and the second member traces an involute curve when viewed in the first direction.
